(19) United States
(12) Patent Application Publication
(10) Pub. No.: US 2023/0006041 A1
(43) Pub. Date: Jan. 5, 2023

(54) SEMICONDUCTOR DEVICE AND METHOD FOR MANUFACTURING THE SAME

(71) Applicant: UNITED MICROELECTRONICS CORP., Hsinchu (TW)

(72) Inventors: Jing-Wen HUANG, Pingtung County (TW); Wei-Hao HUANG, New Taipei City (TW); Chung-Yi CHIU, Tainan City (TW); Lung-En KUO, Tainan City (TW); Kun-Yuan LIAO, Hsinchu City (TW)

(21) Appl. No.: 17/385,961

(22) Filed: Jul. 27, 2021

(30) Foreign Application Priority Data
Jul. 5, 2021 (CN) 202110756407.7

(51) Int. Cl. H01L 29/06; H01L 29/423; H01L 29/786; H01L 29/66

(52) U.S. Cl. CPC H01L 29/0669; H01L 29/42392; H01L 29/78696; H01L 29/66742

(57) ABSTRACT

A semiconductor device is provided. The semiconductor device includes a substrate and a plurality of nanowires. The substrate has an upper surface. The nanowires are stacked on the upper surface of the substrate along a first direction. The nanowires include a triangle in a cross section, and the nanowires include a plane extending along a second direction, a first down-slant facet on a (111) plane, and a second down-slant facet on an additional (111) plane.

This application claims the benefit of People's Republic of China application Serial No. 202110756407.7, filed Jul. 5, 2021, the subject matter of which is incorporated herein by reference.

### BACKGROUND OF THE INVENTION

### Field of the Invention

The invention relates in general to a semiconductor device and a method for manufacturing the same, and more particularly to a gate-all-around semiconductor device and a method for manufacturing the same.

### Description of the Related Art

Recently, the demands for miniaturizing a semiconductor device are increased. The gate-all-around (GAA) semiconductor nanowire field effect transistors (FETs) have advantages in smaller dimensions and better electrical property in comparison with conventional FETs, and the development in GAA semiconductor nanowire FET is getting more and more important, accordingly.

### SUMMARY OF THE INVENTION

The present invention relates to a semiconductor device and a method for manufacturing the same, which can form a nanowire with excellent electrical properties through a simplified process.

According to an embodiment of the present invention, a semiconductor device is provided. The semiconductor device includes a substrate and a plurality of nanowires. The substrate has an upper surface. The nanowires are stacked on the upper surface of the substrate along a first direction. The nanowires include a triangle in a cross section, and the nanowires include a plane extending along a second direction, a first down-slant facet on a (111) plane, and a second down-slant facet on an additional (111) plane.

According to another embodiment of the present invention, a method for manufacturing a semiconductor device is provided. The method includes the following steps. Firstly, a substrate is provided. Then, a stack and a hard mask layer are sequentially formed on the substrate along a first direction, wherein the stack includes a plurality of etch stop layers and a plurality of semiconductor layers alternately stacked. Portions of the substrate, the stack and the hard mask layer are removed to form a plurality of fin structures, wherein each of the fin structures includes a substrate portion, a plurality of etch stop portions, a plurality of semiconductor portions, and a hard mask portion. Thereafter, the substrate portion and the semiconductor portions are patterned by a wet etching process to form a plurality of nanowires. The nanowires are stacked on the upper surface of the substrate along the first direction and extend along the second direction, and include a triangle in a cross section.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1 to 5 show a flowchart of a method for manufacturing a semiconductor device according to one embodiment of the present invention

### DETAILED DESCRIPTION OF THE INVENTION

The present application provides a semiconductor device and a method for manufacturing the same, which can solve the problems of high cost and long time consuming due to the complicated manufacturing process in the prior art. In order to make the objectives, features, and advantages of the present invention more comprehensible, one embodiment is provided below, and is described in detail in conjunction with the accompanying drawings.

However, it must be noted that the specific embodiment and method are not intended to limit the present invention. The present invention can still be implemented using other features, elements, methods, and parameters. The preferred embodiments are only used to illustrate the technical features of the present invention, and not to limit the scope of the claims of the present invention. One of ordinary skill in the art will be able to make equivalent modifications and changes based on the description in the following specification without departing from the spirit of the present invention.

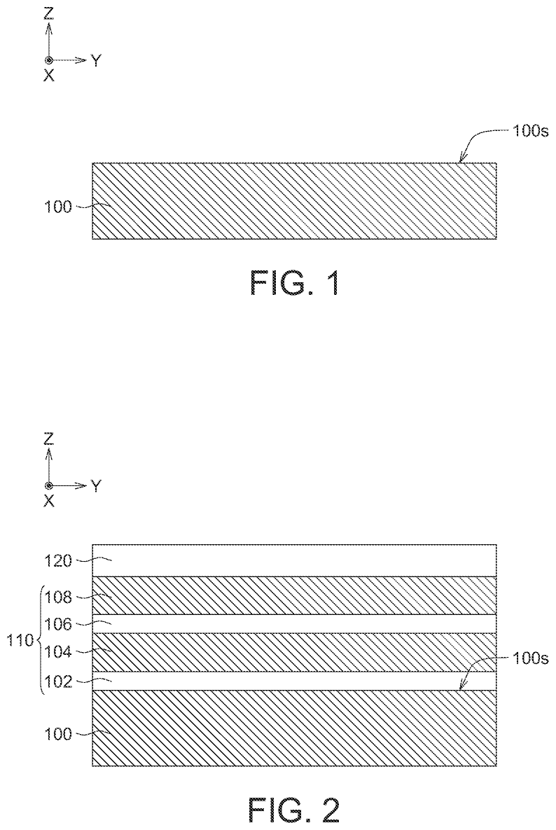

FIGS. 1 to 5 show a flowchart of a method for manufacturing a semiconductor device 10 according to one embodiment of the present invention.

First, referring to FIG. 1, a substrate 100 may be provided. The substrate 100 may have a first surface 100s. In the present embodiment, the substrate 100 may include a single crystalline semiconductor material, such as single crystalline silicon.

Next, a stack 110 and a hard mask layer 120 are sequentially formed on the substrate 100 along the first direction (for example, Z direction), wherein the stack 110 includes a plurality of etch stop layers 102 and 106 and a plurality of semiconductor layers 104 and 108, as shown in FIG. 2. The stack 110, for example, continuously extends on the first surface 100s of the substrate 100 along the second direction (for example, X direction) and the third direction (for example, Y direction). The first direction, the second direction, and the third direction may be intersected with each other. In the present embodiment, the first direction, the second direction, and the third direction may be perpendicular to each other, but the present invention is not limited thereto.

According to one embodiment, the material of the etch stop layers 102 and 106 may include oxide, and the material of the hard mask layer 120 may include nitride, but the present invention is not limited thereto. In one embodiment, the semiconductor layers 104 and 108 may include a single crystalline semiconductor material, such as single crystalline silicon.

According to one embodiment, the method for forming the stack 110 on the substrate 100 may be similar to the method of wafer bonding for forming silicon on insulator (SOI), that is, similar to Bond and Etch-back SOI process (BESOT process).

According to an embodiment, the hard mask layer 120 may be formed by a deposition process, such as chemical vapor deposition (CVD) or plasma-enhanced CVD (PECVD).

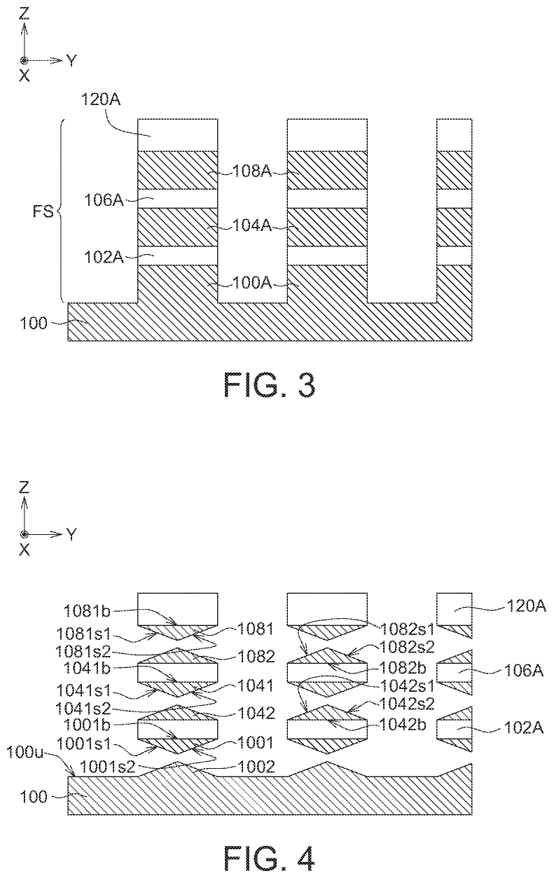

Thereafter, referring to FIG. 3, portions of the substrate 100, the stack 110, and the hard mask layer 120 may be removed along the first direction (Z direction) to form a plurality of fin structures FS. Wherein, the step of removing portions of the substrate 100, the stack 110 and the hard mask layer 120 to form a plurality of fin structures FS is performed by, for example, a dry etching process. The plurality of fin structures FS, for example, respectively protrude on the remaining substrate 100 along the first direction, and respectively extend on the remaining substrate 100 along the second direction. That is, a plurality of fin structures FS may extend parallel to each other and may be separated from each other in the third direction. In the present embodiment, each of the fin structures FS may include a substrate portion 100A, two etch stop portions 102A and 106A, two semiconductor portions 104A and 108A, and a hard mask portion 120A, but the present invention is not limited thereto. In the present embodiment, the widths of the substrate portion 100A, the etching stop portions 102A and 106A, the semiconductor portions 104A and 108A, and the hard mask portion 120A in the third direction are similar or the same, but the present invention is not limited thereto.

After forming the fin structures FS, referring to FIG. 4, the substrate portion 100A and the semiconductor portions 104A and 108A may be patterned by a wet etching process to form nanowires 1081, 1082, 1041, 1042, and 1001 and a substrate protrusion 1002.

In one embodiment, the etchant used in the wet etching process may include tetramethylammonium hydroxide (TMAH) or other suitable etchant. The wet etching process is, for example, selective etching of silicon. The etchant has a faster etching rate for the (111) plane of silicon, and it needs to be etched until the nanowires 1081, 1082, 1041, 1042, and 1001 can be completely disconnected, and the nanowire 1001 and the substrate protrusion 1002 are also completely disconnected. Therefore, the nanowires 1081, 1082, 1041, 1042, and 1001 formed by the wet etching process include a triangle in a cross section (for example, the cross section formed by the first direction and the second direction). The nanowires 1081, 1082, 1041, 1042, and 1001 with triangular cross-sections respectively include a plane 1081b, 1082b, 1041b, 1042b, and 1001b extending along the second direction, a first down-slant facet 1081s1, 1082s1, 1041s1, 1042s1, and 1001s1 on a (111) plane, and a second downs-slant facet 1081s2, 1082s2, 1041s2, 1042s2, and 1001s2 on an additional (111) plane. The nanowires 1081, 1082, 1041, 1042, and 1001 and the substrate protrusion 1002 are stacked on the upper surface 100u of the substrate 100 along the first direction, and extend along the second direction. The substrate protrusion 1002 is also triangular in a cross section, and is connected to the upper surface 100u of the substrate 100. Actually, the substrate protrusion 1002 and the substrate 100 are integrally formed.

As shown in FIG. 4, in the above step of patterning the substrate portion 100A and the semiconductor portions 104A and 108A by the wet etching process, no spacer is formed beside the substrate portion 100A and the semiconductor portions 104A and 108A. In some traditional methods of forming nanowires, spacers need to be formed beside the substrate portion and the semiconductor portions to protect the substrate portion and the semiconductor portions from damage by subsequent processes (such as etching processes), and the formed nanowires are usually rectangular in the cross section. Compared with the comparative example in which spacers are required to protect the substrate portion and the semiconductor portions during the manufacturing process, the method for forming a nanowire according to an embodiment of the present application does not need to form spacers, and triangular nanowires can be formed directly through a wet etching process, so it can omit multiple processes, both in terms of process cost and time have been greatly improved.

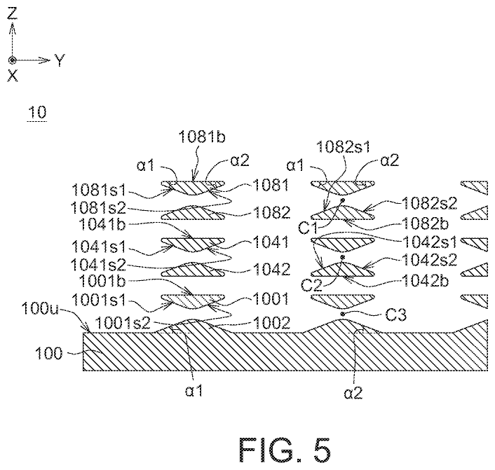

Hereafter, referring to FIG. 5, the etching stop portions 102A and 106A and the hard mask portion 120A can be removed by different etching processes, and the nanowires 1081, 1082, 1041, 1042 and 1001 and the substrate protrusion 1002 can be remained, so as to form a semiconductor device 10. In one embodiment, the etch stop portions 102A and 106A can be removed by an etchant including hydrofluoric acid (HF), and the hard mask portion 120A can be removed by an etchant including phosphoric acid (H₃PO₄), but the present invention is not limited thereto.

In some embodiments, the sharp corners of the nanowires 1081, 1082, 1041, 1042, and 1001 can be further rounded by an anneal process, that is, in the cross section, the nanowires 1081, 1082, 1041, 1042, and 1001 may include triangles with round corners. In this way, the nanowires 1081, 1082, 1041, 1042, and 1001 can have better electrical properties, such as avoiding current leakage. After that, a subsequent process can be performed to form a gate dielectric material layer (not shown) surrounding the nanowires 1081, 1082, 1041, 1042, and 1001, and then a conductive material may be filled between the gate dielectric material layers (not shown) to form a conductive gate (not shown) surrounding the nanowires 1081, 1082, 1041, 1042, and 1001 and the gate dielectric material layer (not shown). In other words, the semiconductor device 10 can be applied to a gate-all-around semiconductor nanowire field effect transistor.

As shown in FIG. 5, the semiconductor device 10 may include a substrate 100 and a plurality of nanowires 1081, 1082, 1041, 1042, and 1001. The substrate 100 has an upper surface 100u. The nanowires 1081, 1082, 1041, 1042, and 1001 are stacked on the upper surface 100u of the substrate 100 along a first direction (for example, Z direction). The nanowires 1081, 1082, 1041, 1042, and 1001 include a triangle in a cross section. The topmost nanowire 1091 and the bottommost nanowire 1001 in the nanowires 1081, 1082, 1041, 1042, and 1001 stacked along the first direction are inverted triangles in the cross section. The nanowires 1081, 1082, 1041, 1042, and 1001 include planes 1081b, 1082b, 1041b, 1042b, and 1001b extending along a second direction (for example, X direction), a first down-slant facet 1081s1, 1082s1, 1041s1, 1042s1, and 1001s1 on a (111) plane, and a second down-slant facet 1081s2, 1082s2, 1041s2, 1042s2, and 1001s2 on an additional (111) plane. In the present embodiment, the planes 1081b, 1082b, 1041b, 1042b, and 1001b may be parallel to the upper surface 100u of the substrate 100, but the present invention is not limited to thereto.

In the present embodiment, the amount of nanowires 1081, 1082, 1041, 1042, and 1001 stacked along the first direction is 5, but the present invention is not limited thereto, and the amount of nanowires can be any odd number. In one embodiment, when the amount of semiconductor layers is n (as shown in FIG. 2, the amount of semiconductor layers 104 and 108 is 2), the amount of nanowires is 2n+1 (as shown in FIG. 5, the amount of nanowires 1081, 1082, 1041, 1042, and 1001 is 2×2+1=5), and n is a positive integer. In comparison with the comparative example in which the semiconductor layers or semiconductor portions are not respectively separated into the upper and lower triangles (i.e. two triangles), since n semiconductor layers or n semiconductor portions are respectively separated into upper and lower triangles to form 2n+1 nanowires by the wet etching in the present invention, the semiconductor device of the present invention can include a larger amount of nanowires, and make the contact area between the nanowires 1081, 1082, 1041, 1042 and 1001 and the gate (not shown) become larger, so that the conducting effect can be improved, and the semiconductor device 10 may have better electrical properties, accordingly.

In one embodiment, the included angles α1 between the planes 1081b, 1082b, 1041b, 1042b, and 1001b and the first down-slant facets 1081s1, 1082s1, 1041s1, 1042s1, and 1001s1 may range from 54.5 degrees to 55 degrees, such as 54.7 degrees; the included angles α2 between the planes 1081b, 1082b, 1041b, 1042b, and 1001b and the second down-slant facets 1081s2, 1082s2, 1041s2, 1042s2, and 1001s2 may range from 54.5 degrees to 55 degrees, such as 54.7 degrees. The substrate 100 and the nanowires 1081, 1082, 1041, 1042, and 1001 may include a single crystalline semiconductor material, such as single crystalline silicon.

According to one embodiment, at least two of the nanowires 1081, 1082, 1041, 1042, and 1001 may be symmetrical to each other along the second direction. For example, there may be a center point C1 between the nanowires 1081 and 1082, a center point C2 between the nanowires 1041 and 1042, and a center point C3 between the nanowire 1001 and the substrate protrusion 1002. The nanowire 1081 may be mirror-symmetrical to the nanowire 1082 on a symmetry axis passing through the center point C1 and extending along the second direction. The nanowire 1041 may be mirror-symmetrical to the nanowire 1042 on a symmetry axis passing through the center point C2 and extending along the second direction. The nanowire 1001 may be mirror-symmetrical to the substrate protrusion 1002 on a symmetry axis passing through the center point C3 and extending along the second direction.

According to the above-mentioned embodiment, the present invention provides a semiconductor device and a manufacturing method thereof. Compared with the conventional comparative example in which spacers are required to be formed beside the substrate portions and the semiconductor portions, the method for manufacturing the semiconductor device of the present invention can pattern the substrate portions and the semiconductor portions by a wet etching process, to form a plurality of nanowires including triangles in the cross section, it is not necessary to form spacers beside the substrate portions and the semiconductor portions, so the conventional complicated process can be simplified, and the process cost and time can be greatly improved. In addition, compared with the comparative example in which the amount of nanowires is n (n is a positive integer) when the amount of semiconductor layers is n, in the semiconductor device of the present invention, when the amount of semiconductor layers is n, the amount of nanowires can be 2n+1 (n is a positive integer), that is, the amount of nanowires can be larger, which can form the semiconductor device with more densely stacked nanowires. Further, there can be a larger contact area between the nanowires and the gate, so that the conducting effect can be increased, and the semiconductor device may have better electrical properties.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a substrate having an upper surface; and
a plurality of nanowires stacked on the upper surface of the substrate along a first direction;
wherein the nanowires comprise a triangle in a cross section, and the nanowires comprise a plane extending along a second direction, a first down-slant facet on a (111) plane, and a second down-slant facet on an additional (111) plane.

2. The semiconductor device according to claim 1, wherein an included angle between the plane and the first down-slant facet ranges from 54.5 degrees to 55 degrees, and an included angle between the plane and the second down-slant facet ranges from 54.5 degrees to 55 degrees.

3. The semiconductor device according to claim 1, wherein at least two of the nanowires are symmetrical to each other along the second direction.

4. The semiconductor device according to claim 1, wherein the substrate and the nanowires comprise a single crystalline semiconductor material.

5. The semiconductor device according to claim 1, wherein an amount of the nanowires stacked along the first direction is an odd number.

6. The semiconductor device according to claim 1, wherein a topmost nanowire and a bottommost nanowire in the nanowires stacked along the first direction are inverted triangles in the cross section.

7. A method for manufacturing a semiconductor device, comprising:
providing a substrate;
sequentially forming a stack and a hard mask layer on the substrate along a first direction, wherein the stack comprises a plurality of etch stop layers and a plurality of semiconductor layers alternately stacked;
removing portions of the substrate, the stack and the hard mask layer to form a plurality of fin structures, wherein each of the fin structures comprises a substrate portion, a plurality of etch stop portions, a plurality of semiconductor portions, and a hard mask portion; and
patterning the substrate portion and the semiconductor portions to form a plurality of nanowires by a wet etching process, wherein the nanowires are stacked on an upper surface of the substrate along the first direction and extend along a second direction, and the nanowires comprise a triangle in a cross section.

8. The method for manufacturing the semiconductor device according to claim 7, wherein an etchant used in the wet etching process comprises tetramethylammonium hydroxide.

9. The method for manufacturing the semiconductor device according to claim 7, wherein in the step of patterning the substrate portion and the semiconductor portions to form a plurality of nanowires by a wet etching process, no spacer is formed beside the substrate portion and the semiconductor portions.

10. The method for manufacturing the semiconductor device according to claim 7, wherein at least two of the nanowires are symmetrical to each other along the second direction.

11. The method for manufacturing the semiconductor device according to claim 7, wherein the nanowires comprise a plane extending along the second direction, a first down-slant facet on a (111) plane, and a second down-slant facet on an additional (111) plane.

12. The method for manufacturing the semiconductor device according to claim 11, wherein an included angle between the plane and the first down-slant facet ranges from 54.5 degrees to 55 degrees, and an included angle between the plane and the second down-slant facet ranges from 54.5 degrees to 55 degrees.

13. The method for manufacturing the semiconductor device according to claim 11, wherein the substrate and the nanowires comprise a single crystalline semiconductor material.

14. The method for manufacturing the semiconductor device according to claim 7, wherein an amount of the nanowires stacked along the first direction is an odd number.

15. The method for manufacturing the semiconductor device according to claim 7, wherein an amount of the semiconductor layers is n, an amount of the nanowires is 2n+1, and n is a positive integer.

16. The method for manufacturing the semiconductor device according to claim 7, wherein the step of removing portions of the substrate, the stack and the hard mask layer to form a plurality of fin structures is performed by a dry etching process.
